(19) United States
(12) Patent Application Publication
(10) Pub. No.: US 2025/0140626 A1
(43) Pub. Date: May 1, 2025

(54) SENSOR ELECTRONIC DEVICE

(71) Applicant: Texas Instruments Incorporated, Dallas, TX (US)

(72) Inventors: Masamitsu Matsuura, BEPPU-SHI OITA-KEN (JP); Daiki Komatsu, BEPPU-SHI OITA-KEN (JP); Kengo Aoya, BEPPU-SHI OITA-KEN (JP)

(21) Appl. No.: 18/495,837

(22) Filed: Oct. 27, 2023

(51) Int. Cl. H01L 23/31; H01L 21/56; H01L 23/00

(52) U.S. Cl. CPC H01L 23/315; H01L 21/565; H01L 24/48; H01L 2224/48227; H01L 2924/1811

(57) ABSTRACT

An electronic device includes a package structure having opposite first and second sides, opposite third and fourth sides spaced along a first direction, opposite fifth and sixth sides spaced along an orthogonal second direction, the first and second sides spaced along a third direction orthogonal to the first and second directions, and an opening extending into the first side along the third direction, a first semiconductor die having a first side exposed in the opening of the package structure and an opposite second side partially enclosed by the package structure, and a second semiconductor die electrically connected to the first semiconductor die, the second semiconductor die enclosed by the package structure and laterally spaced apart from the first semiconductor die.

### BACKGROUND

Integrated circuit pressure sensors can use micro electromechanical system (MEMS) sensor membrane to detect pressure, with a glass cap and an application specific integrated circuit (ASIC) stacked on top of a membrane MEMS die. However, the resulting device has a high profile that can be undesirable in some applications. In addition, the MEMS die must be etched during wafer fabrication to create a cavity and a sensing face membrane exposed to the atmosphere for sensing pressure, and a reference cavity must be etched into the bottom of a glass cap during wafer processing. Manufacturing this type of pressure sensor is expensive, requiring multiple wafer-level processing operations and masks in a complex process flow that is not cost-effective.

### SUMMARY

In one aspect, an electronic device includes a package structure and first and second semiconductor dies. The package structure has opposite first and second sides, opposite third and fourth sides spaced along a first direction, opposite fifth and sixth sides spaced along an orthogonal second direction, the first and second sides spaced along a third direction orthogonal to the first and second directions, and an opening extending into the first side along the third direction, The first semiconductor die has a first side exposed in the opening of the package structure and an opposite second side partially enclosed by the package structure, and the second semiconductor die is electrically connected to the first semiconductor die, enclosed by the package structure, and laterally spaced apart from the first semiconductor die.

In another aspect, a system includes an electronic device and circuit board. The electronic device includes a package structure and first and second semiconductor dies. The package structure has opposite first and second sides, opposite third and fourth sides spaced along a first direction, opposite fifth and sixth sides spaced along an orthogonal second direction, the first and second sides spaced along a third direction orthogonal to the first and second directions, and an opening extending into the first side along the third direction. The first semiconductor die has a first side exposed in the opening of the package structure and an opposite second side partially enclosed by the package structure and the second semiconductor die is electrically connected to the first semiconductor die. The second semiconductor die is enclosed by the package structure and laterally spaced apart from the first semiconductor die.

In a further aspect, a method of fabricating an electronic device includes positioning a semiconductor die with a side of the semiconductor die coplanar with a bottom side of a conductive lead feature of a lead frame, forming a molded package structure that encloses a portion of the conductive lead feature, and etching an exposed side of the semiconductor die to form an opening extending into the bottom side of the molded package structure.

### BRIEF DESCRIPTION OF THE DRAWINGS

FIG. 1 is a partial sectional side elevation view taken along line 1-1 of FIG. 1A showing a sensor system with a pressure sensor electronic device having side-by-side MEMS sensor and ASIC dies and an opening in a molded package structure that exposes the bottom side of the MEMS sensor die and a cap die that forms a closed reference pressure cavity on a top side of the MEMS sensor die.

FIG. 1A is a bottom view of the electronic device of FIG. 1.

FIG. 1B is a partial sectional side elevation view of another pressure sensor electronic device having a film cap that forms a closed reference pressure cavity on a top side of a MEMS sensor die.

FIG. 2 is a flow diagram of a method of fabricating an electronic device.

FIGS. 3-13 are partial sectional side elevation views of the pressure sensor electronic device of FIGS. 1 and 1A undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”. “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to electronic devices and systems and/or to manufacturing an electronic device such as an integrated circuit. While such examples may be expected to provide various improvements, no particular result is a requirement of the present disclosure unless explicitly recited in a particular claim.

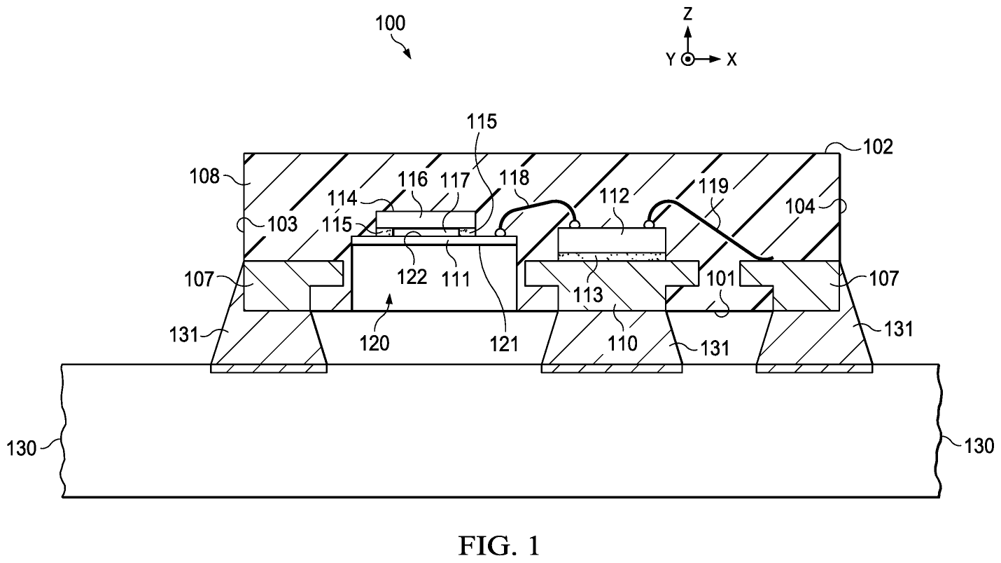

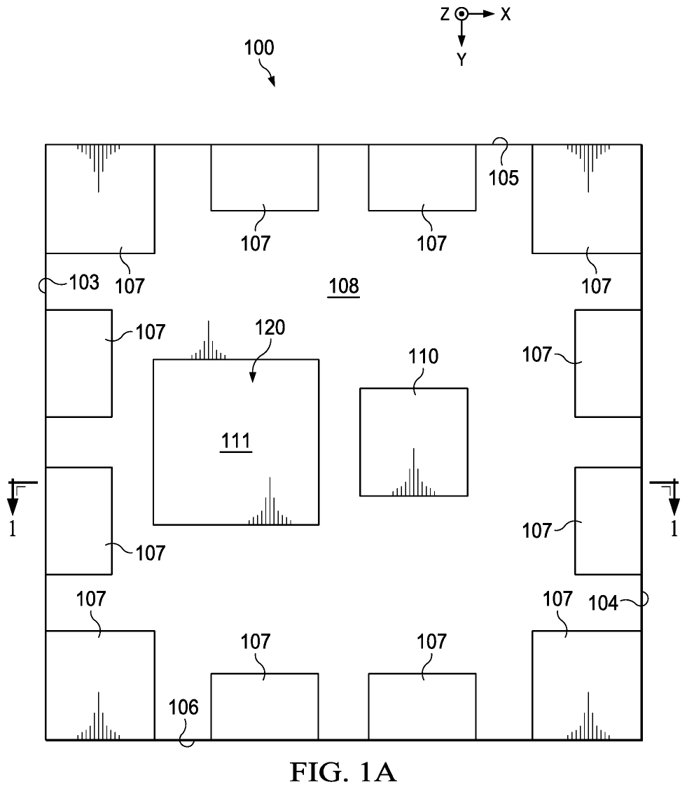

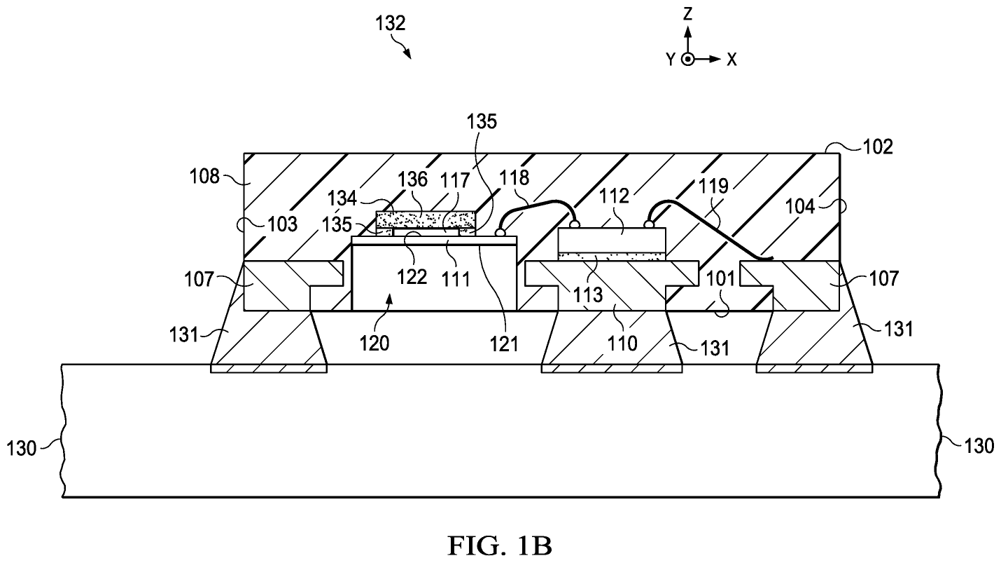

FIGS. 1 and 1A show an example quad flat no-lead (QFN) packaged electronic device 100 in an example position in a three-dimensional space with a first direction X, a perpendicular (orthogonal) second direction Y, and a third direction Z that is perpendicular (orthogonal) to the respective first and second directions X and Y. Structures or features along any two of these directions are orthogonal to one another. The electronic device 100 and a molded package structure 108 thereof have opposite first and second (e.g., bottom and top) sides 101 and 102 (FIG. 1), respectively, which are spaced apart from one another along the third direction Z in the illustrated position. The electronic device 100 and the molded package structure 108 also have opposite third and fourth sides 103 and 104 that are spaced apart from one another along the first direction X, and fifth and sixth sides 105 and 106 (FIG. 1A) that are spaced apart from one another along the second direction Y in the illustrated position.

The electronic device 100 also has conductive metal leads 107 partially exposed outside the molded package structure 108 along the bottom or first side 101. In various example implementations, the electronic device 100 can have any integer number of one or more instances of the leads 107 with a respective lateral side at least partially exposed outside the package structure 108 along a respective one or more of the lateral sides 103-106. Although the illustrated example has a no lead package shape with substantially flush leads 107 along all four lateral sides 103-106, other partially extending leads can be used in other examples (e.g., j-leads, gull wing leads, stub leads, combinations thereof, etc., not shown) alone or in combination with one or more flush leads 107 along any one or more of the lateral sides 103-106. In the illustrated QFN example, moreover, the conductive leads 107 have lower or bottom sides that are configured for soldering to conductive pads or structures of a host printed circuit board 130 of a sensor system as shown in FIG. 1.

The electronic device 100 also includes a die attach pad 110, such as a conductive metal for example that is or includes copper, aluminum, or other suitable metal or alloys thereof. In the example of FIGS. 1 and 1A, the bottom side of the die attach pad 110 is substantially flush with the bottom or first side 101 of the electronic device 100, and the bottom side of the die attach pad 110 is exposed outside the molded package structure 108 along the first side 101, as best shown in FIG. 1A. As seen in FIG. 1A, for example, the bottom side of the die attach pad 110 can operate as a heatsink or thermal pad when the electronic device 100 is installed on the circuit board 130 of a host system in order to facilitate removal of heat from the electronic device 100 during powered operation in the host system. In another possible implementation, the bottom side of the die attach pad 110 is enclosed (e.g., covered) by the molded package structure 108.

The electronic device 100 has a first semiconductor die 111 and a second semiconductor die 112. As further shown in FIG. 1, the electronic device 100 is installed in a system for operation as a low profile compact pressure sensor with side-by-side first and second dies 111 and 112 (e.g., MEMS sensor die 111 and ASIC die 112) and an opening 120 in the molded package structure 108 that exposes a bottom or first side 121 of the MEMS sensor first semiconductor die 111 and a cap 114 forms a closed reference pressure cavity 117 on a top or second side 122 of the MEMS sensor first semiconductor die 111. The second semiconductor die 112 in one example is attached to a top side of the die attach pad 110 by a conductive or non-conductive die attach adhesive 113. The first semiconductor die 111 is a MEMS die in one example. In this or another example, the second semiconductor die 112 is an ASIC die and is electrically connected to the first semiconductor die 111. The second semiconductor die 112 is enclosed by the package structure 108 and is laterally spaced apart from the first semiconductor die 111 along the first direction in the orientation illustrated in FIG. 1.

The example electronic device in FIGS. 1 and 1A includes a cap 114 with a top or lid 116 formed by a third semiconductor die. The lid 116 is supported by a cured die attach adhesive structure 115. The die attach adhesive 115 form sidewalls of the cap 114 and the cap 114 forms a closed reference pressure cavity 117 above a portion of the first semiconductor die 111. In one example, the reference pressure cavity 117 is sealed during manufacturing. The cap 114 is attached to the second side 122 of the first semiconductor die 111 and defines the closed reference pressure cavity 117 above a portion of the second side 122 of the first semiconductor die 111.

The first semiconductor die 111 is configured to detect a sensed pressure of the first side 121 of the first semiconductor die 111 relative to the pressure of the second side 122 of the first semiconductor die 111 (e.g., the pressure of the reference pressure cavity 117). The first semiconductor die 111 is configured to provide an electrical signal to the second semiconductor die 112 based on the sensed pressure. In one example, the first semiconductor die 111 includes sensor components that convert pressure signals into electrical signals via small strain gauges implanted in the thin semiconductor area, referred to as a membrane or diaphragm, that extends between the reference pressure cavity 117 and the first (e.g., bottom) side 121 of the first semiconductor die 111. In certain examples, the sensor components can be silicon piezoresistive pressure sensors, silicon capacitive pressure sensors, surface acoustic wave (SAW) pressure sensors, etc. In one or more implementations, the first and/or second semiconductor dies 111, 112 can include integrated digital and/or analog signal conditioning components and circuitry for drift, sensitivity, and/or linearity compensation.

In one example, the first semiconductor die 111 provides capacitive MEMS pressure sensing or detection functionality by having one or more conductive layers (not shown) on the bottom first side 121 and/or the top second side (122) that form one or more capacitors with a conductive layer (not shown) on the third semiconductor die 116. In another example, one or more capacitors are formed between a conductive layer on one of the sides 121 and 122 of the first semiconductor die 111 and a conductive layer on the bottom side of the third semiconductor die 116. In one example, the capacitor has a nominal capacitance of 1-10 pH in one example when the ambient (e.g., sensed) pressure at the first side of the first semiconductor die 111 is approximately the same as the pressure in the closed reference pressure cavity 117 on a portion of the second (top) side 122 of the first semiconductor die 111.

The portion of the first semiconductor die 111 under the closed reference pressure cavity 117 acts as a diaphragm and moves in response to the differential pressure of the first side 121 relative to the reference pressure in the closed cavity 117, and the diaphragm movement or displacement changes the spacing between the conductors that form the sense capacitor plates, resulting in a change in the capacitance that represents the sensed pressure at the first side 121 relative to the reference pressure in the closed cavity 117. The first semiconductor die 111 in one example detects the sensed pressure of the first side 121 of the first semiconductor die 111 relative to the pressure of the second side 122 of the first semiconductor die 111 (e.g., the pressure of the reference pressure cavity 117) based on the sensed capacitance. The first semiconductor die 111 provides an electrical signal to the second semiconductor die 112 based on the sensed pressure. The first semiconductor die 111 and/or the second semiconductor die 112 in one example includes circuitry to detect the capacitance or capacitance change from a nominal value including a tuned oscillator circuit with an operating frequency that changes with pressure or an RC charging circuit including the sensor capacitor(s) to generate an output signal based on the time to charge the capacitor from a current source (not shown).

In another example, the first semiconductor die 111 can include one or more MEMS piezoresistive strain gauge sensors formed as conductors on the diaphragm and connected in a bridge circuit (not shown). In operation, a differential pressure of the first side 121 relative to the reference pressure in the closed cavity 117 changes the resistance of the conductors to detect the differential pressure by a bridge circuit (e.g., Wheatstone bridge) signal. In these or other examples, the first semiconductor die 111 can implement a MEMS surface acoustic wave (SAW) pressure sensor that generates vibrations through the membrane or diaphragm. The first semiconductor die 111 can include a transducer that receives the waves and detects changes in the amplitude or phase of the acoustic signal caused by deformation of the surface to provide an output signal based on the detected pressure.

In the example of FIG. 1, the electronic device 100 includes bond wire electrical connections. A first bond wire 118 is electrically connected between a conductive terminal (e.g., a metal bond pad) of the first semiconductor die 111 and a conductive terminal of the second semiconductor die 112. A second bond wire 119 in FIG. 1 is electrically connected between the second semiconductor die 112 and one of the conductive leads 107. In other examples, other types of electrical connections can be used in the electronic device 100, such as lead frames, substrates, etc. (not shown), alone or in combination with one or more bond wires.

The electronic device 100 is soldered to conductive pads of the circuit board 130 in the system of FIG. 1 by solder 131 and the circuit board 130 in this example is spaced apart from the bottom of the electronic device 100 along the third direction Z to expose the device opening 120 to an ambient pressure of the system for measurement thereof by the electronic device 100. The electronic device 100 is attached to the circuit board 130, such as by soldering using solder paste that is reflowed to create the solder joints 131 using a surface mount technology (SMT) soldering process. The opening 120 of the package structure 108 extends into the first side 101 of the electronic device along the third direction Z. The first (e.g., bottom) side 121 of the first semiconductor die 111 is exposed in the opening 120 of the package structure 108 and the opposite (e.g., top) second side 122 of the first semiconductor die 111 is partially enclosed by the package structure 108. The opening 120 provides access of the first side 121 of the first semiconductor die 111 to detect the environmental pressure of the system.

The die attach pad 110 and the second semiconductor die 112 are laterally spaced apart from the first semiconductor die 111 and the opening 120 in a plane of the first and second directions X and Y. In the illustrated example, no part of the second semiconductor die 112 is above the first semiconductor die 111. The side-by-side arrangement of the first and second semiconductor dies one 111 and 112 provides a low profile electronic device structure 100 compared with stacked arrangements of a MEMS die and an ASIC die.

The thickness of the first semiconductor die 111 (e.g., the distance between the first and second sides 121 and 122 along the third direction Z) can be tailored for a given pressure sensing application. In the illustrated example, the bottom or first side 121 of the first semiconductor die 111 is etched during manufacturing after mold processing to set the final thickness of the first semiconductor die 111. The etching creates the opening 120 with the first side 121 of the first semiconductor die 111 spaced apart from the first side 101 of the package structure 108 along the third direction Z. The package structure 108 has sidewalls of the opening 120 that extend along the third direction Z from the first side 121 of the first semiconductor die 111 to the first side 101 of the package structure 108 as best shown in FIG. 1.

FIG. 1B shows a sectional side view of another example pressure sensor electronic device 132 mounted to a circuit board 130 in a pressure sensing system application. This example includes instances of the structures, features, and materials 101-104, 107, 108, 110-113, 117, 120-122, 130, and 131 as described above. In this example, the electronic device 132 has a film cap 134 that forms a closed reference pressure cavity 117 on the top or second side 122 of the first semiconductor die 111. The cap 134 includes a die attach adhesive material that forms a sidewall 135 of the closed reference pressure cavity 117 as well as a lid 136 of the cap that is spaced apart from the second side 122 of the first semiconductor die 111 along the third direction Z above the closed reference pressure cavity 117.

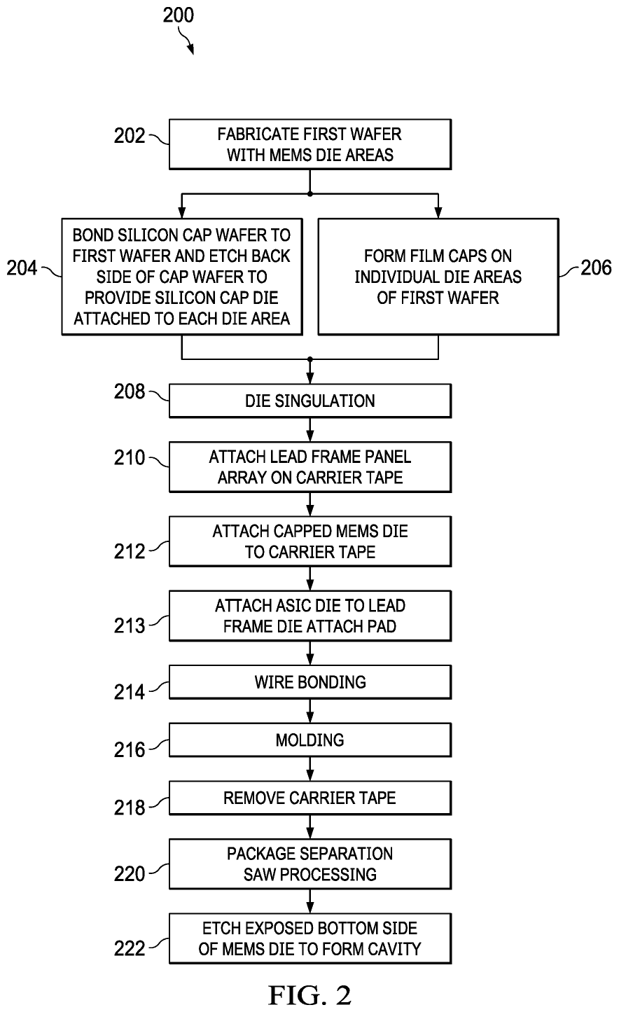

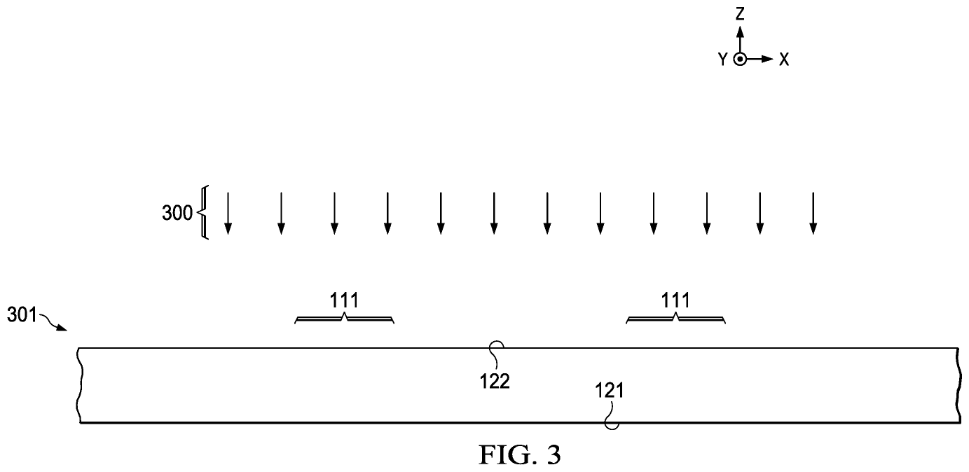

Referring also to FIGS. 2-13, FIG. 2 shows an example method 200 of fabricating an electronic device and FIGS. 3-13 show side views of the pressure sensor electronic device 100 of FIGS. 1 and 1A undergoing fabrication processing according to the method 200. The method 200 and the above described electronic devices 10 and 132 provide advantages and cost benefits with respect to manufacturing MEMS-based sensors for pressure sensing and other sensor applications, including reducing wafer-level etch processing steps and associated masks. In particular, stacked arrangements of MEMS and ASIC dies typically require bottom cavity etching and associated masks as well as MEMS formation processing at the wafer level. The method 200, in contrast, forms the MEMS die bottom side 121 after package molding without requiring an etch mask for MEMS formation or cavity formation. In the illustrated example, the MEMS thin-film formation is set to the thickness between the first and second sides 121 and 122 of the first semiconductor die 111 and to create the package opening 120 by a blanket silicon etch process without an etch mask.

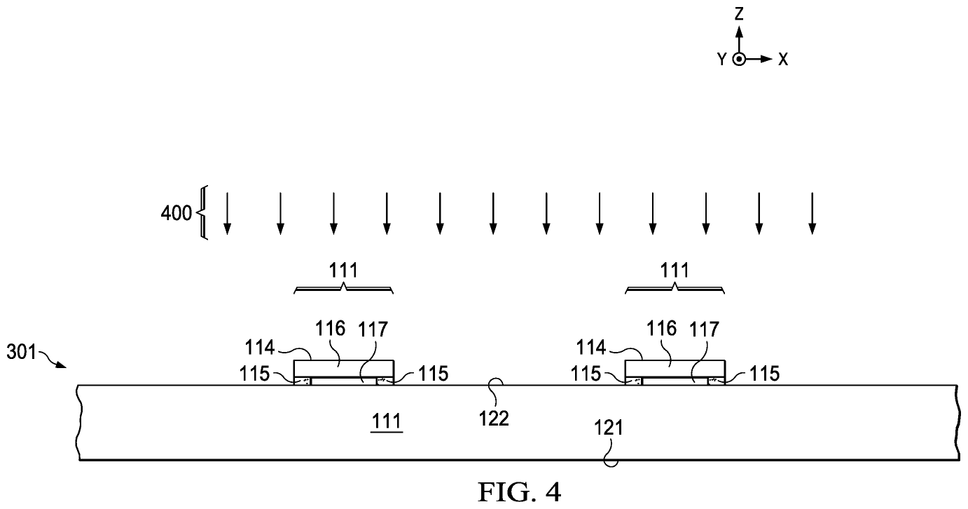

The method 202 includes wafer processing at 202 to fabricate a first wafer with MEMS die areas. FIG. 3 shows one example, in which a wafer-level process 300 is performed that forms MEMS sensor elements on and/or in a semiconductor wafer 301 having a starting bottom or first side 121 and a top or second side 122 as described above. The wafer 301 in one example is a silicon wafer that includes multiple die areas designated 111 in FIGS. 3 and 4 that individually correspond to a subsequently separated first semiconductor die 111. In other examples, a different type of semiconductor wafer can be used. The process 300 forms conductive features, such as traces for MEMS strain gauges, capacitor plates, resistor structures, surface acoustic wave transducers, etc. (not shown) on the second side 122 of the first semiconductor wafer 301.

The method 200 in one example continues at 204 or 206 in FIG. 2 with attaching a cap to the second side 122 of the die areas 111 of the wafer 301. FIG. 4 shows one example, in which a cap attachment process 400 is performed at 204 in FIG. 2 that attaches an instance of the cap 114 to a respective portion of the second side 122 of the semiconductor wafer 301 in each die area designated 111. The instances of the cap 114 in this example include another semiconductor die 116 that forms a lid of the closed reference pressure cavity 117 that is spaced apart from the second side 122 of the semiconductor die 111. The attachment process 400 in this example includes forming and patterning a die attach adhesive 115 that forms a sidewall of the closed reference pressure cavity 117 in each die area of the wafer 301.

In one implementation, a separate semiconductor wafer (e.g., referred to as a cap wafer) is processed to form the lid dies 116 by selective etching spaces between prospective lids. The example attachment process 400 includes forming and patterning the die attach adhesive material to create the sidewall structures 115, and die bonding of the two wafers with the cap lid instances bonded to the respective portions of the second side 122 of the wafer 301. The process 400 in this example also includes back grinding to remove the material from the cap wafer between the respective lids 116 to produce the structures shown in FIG. 4 with a finished cap and the die attach adhesive 115 forming the sidewalls of the closed reference pressure cavities 117.

In another example implementation, the reference cavity 117 is created at 206 in FIG. 2 by forming a film cap 134 on the individual die areas of the first wafer 301. In this example, the cap 134 includes a die attach adhesive that forms: the lid 136 of the closed reference pressure cavity 117 that is spaced apart from the second side 122 of the semiconductor die 111 and the sidewall 135 of the closed reference pressure cavity 117, as illustrated and described above in FIG. 1B. In one implementation, the processing at 206 includes attaching a laminate structure with a film material 135 attached to the second side 122 of the first wafer 301 and patterning the material 135 to form the sidewalls of the prospective cap structure in each unit area of the wafer 304. In this example, a second laminate structure is attached to the tops of the sidewall features 135, and the second laminate structure is patterned to form the lid portions 136 of the cap structure 134.

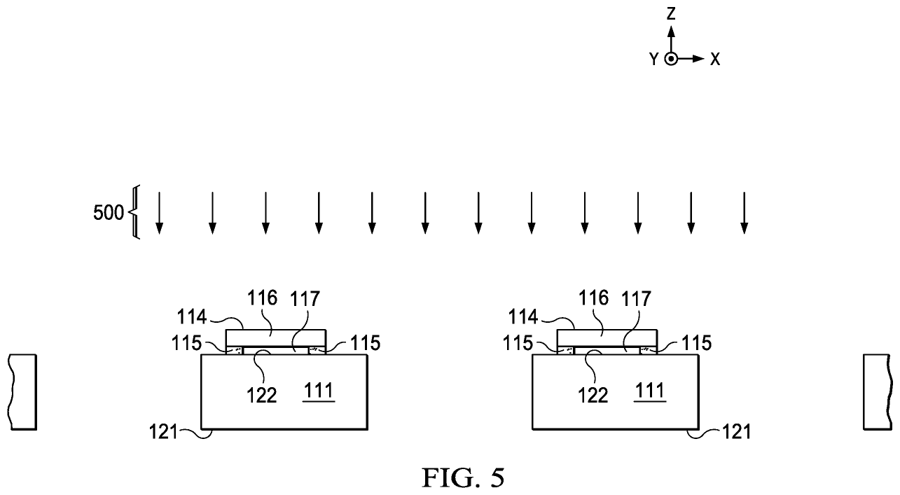

The method 200 continues at 208 in FIG. 2 with die singulation processing. FIG. 5 shows one example, in which a die singulation process 500 is performed that singulates or otherwise separates individual instances of the first semiconductor die 111 from the starting wafer. Any suitable wafer dicing process can be used at 208.

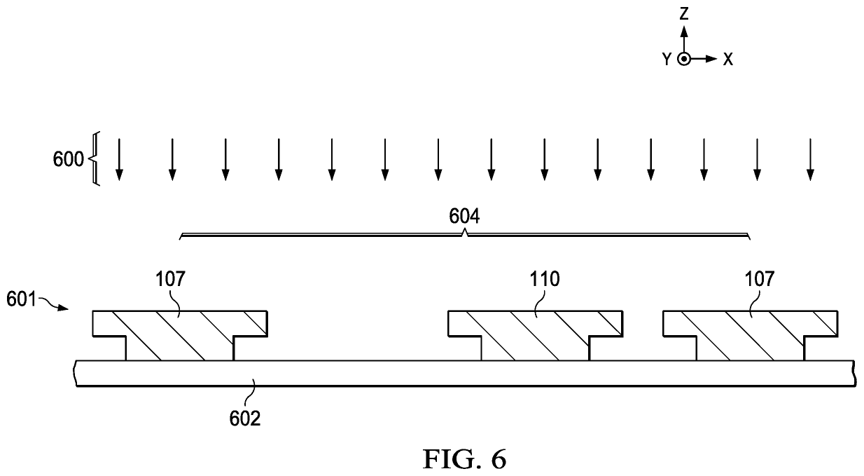

At 210 in FIG. 2, the method 200 in one example includes attaching a lead frame panel array on a carrier tape or other suitable carrier structure. FIG. 6 shows one example, in which a lead frame panel array 601 is attached by an attachment process 600 to an upper adhesive side of a carrier tape 602. In one implementation, the lead frame panel array 601 includes multiple rows and columns of prospective unit areas 604 that individually correspond to a prospective electronic device being manufactured, one of which is shown in FIG. 6. The illustrated unit area 604 in this example includes portions of the prospective conductive leads 107 that are initially contiguous with corresponding leads of an adjacent unit areas 604, as well as the example die attach pad structure 110, where the lead frame features in this example include half etch features to facilitate mold adhesion and mitigate delamination in the finished electronic devices, although not a requirement of all possible implementations. The process 600 in one example positions and attaches the lead frame 601 on the carrier 602 with the bottom side of the conductive lead feature 107 engaging a first portion of the adhesive top side of the carrier 602.

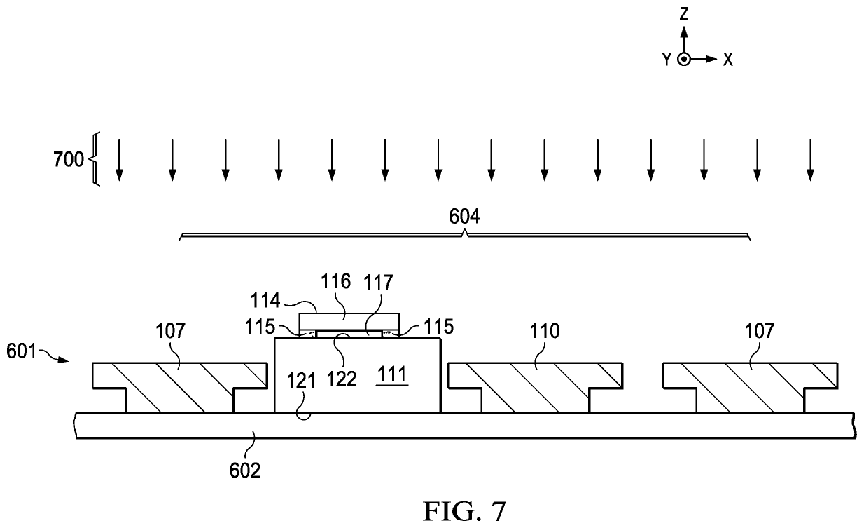

The method 200 continues with die attach processing at 212 and 213 in FIG. 2. At 212, the first semiconductor die 111 is attached to a second portion of the adhesive top side of the carrier tape 602 in each unit area of the panel array. FIG. 7 shows one example of an attachment process 700, in which an instance of the first semiconductor die 111 and the previously attached cap 114 is positioned on the carrier tape 602 in the illustrated unit area 604 with the bottom or first side 121 of the semiconductor die 111 engaging the adhesive top side of the carrier tape 602 and coplanar with a bottom side of a conductive lead features 107 and the bottom side of the die attach pad 110 of the lead frame 601. In one example, the attachment process 700 uses automated pick and place equipment (not shown).

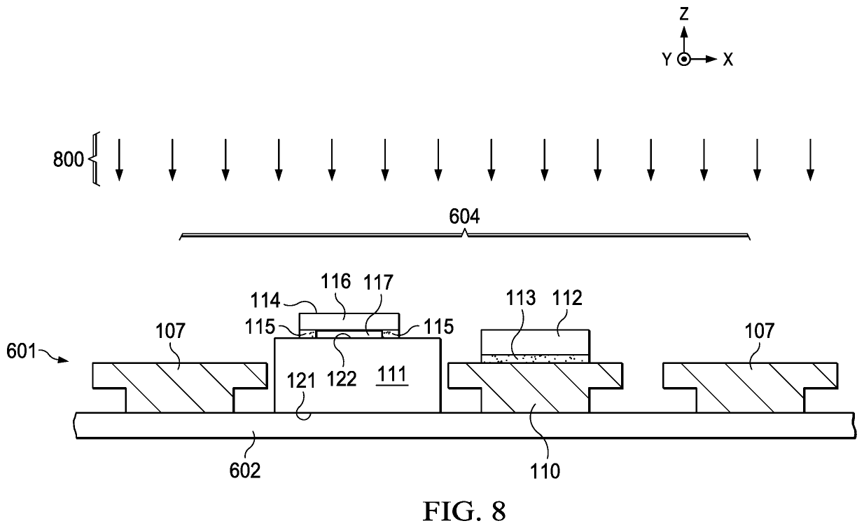

At 213 in FIG. 2, the method 200 includes attaching an instance of the second semiconductor die 112 in each unit area of the panel array. FIG. 8 shows one example, in which a continuation of the first die attach process or a second die attach process 800 is performed that attaches the second semiconductor die 112 on a top side of the die attach pad 110 in each unit area 604 of the panel array. In one example, the process 800 includes dispensing the die attach adhesive material 113 on a select portion of the top side of the die attach pad 110 in each unit area 604 and using automated pick and place equipment to attach the instances of the second semiconductor die 112 on the die attach adhesive material 113 above the top side of the die attach pad 110 in each unit area 604. In one example, the die attach process 800 can include a subsequent adhesive curing step (e.g., thermal, UV, etc.), although not a requirement of all possible implementations.

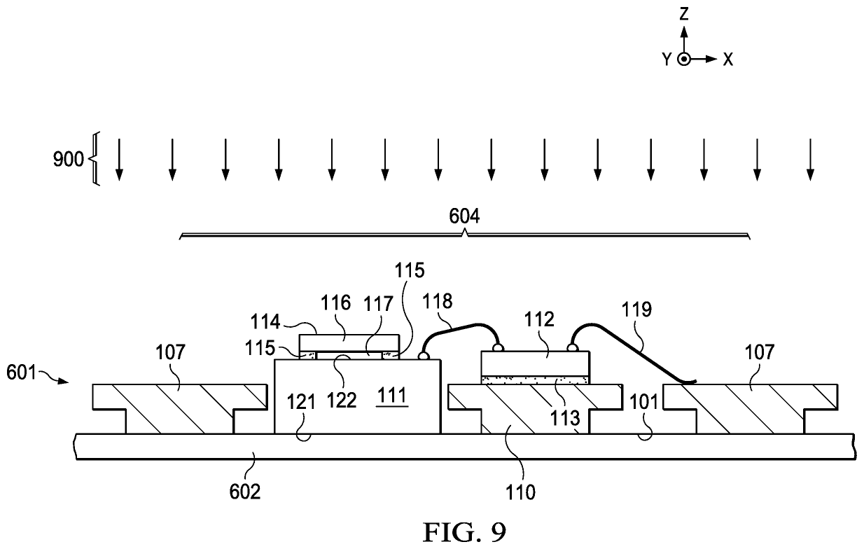

The method 200 continues at 214 in FIG. 2 with electrical connection processing to form one or more electrical interconnections between any two or more of the conductive leads 107, the first semiconductor die 111, the second semiconductor die 112 or combinations thereof. FIG. 9 shows one example, in which a wire bonding electrical connection process 900 forms a bond wire 118 that electrically connects a terminal of the first semiconductor die 111 to a first terminal of the second semiconductor die 112. The wire bonding process 900 in this example also forms a second bond wire 119 in the illustrated unit area 604 that electrically connects a second terminal of the second semiconductor die 112 to a conductive lead feature 107 of the lead frame 601. Any suitable number of bond wires or other electrical interconnection structures (e.g., conductive metal clips, routable lead frames or other single or multilevel package substrates, etc.) can be formed or attached for any desired electrical interconnections in the individual unit areas 604 of the lead frame panel array.

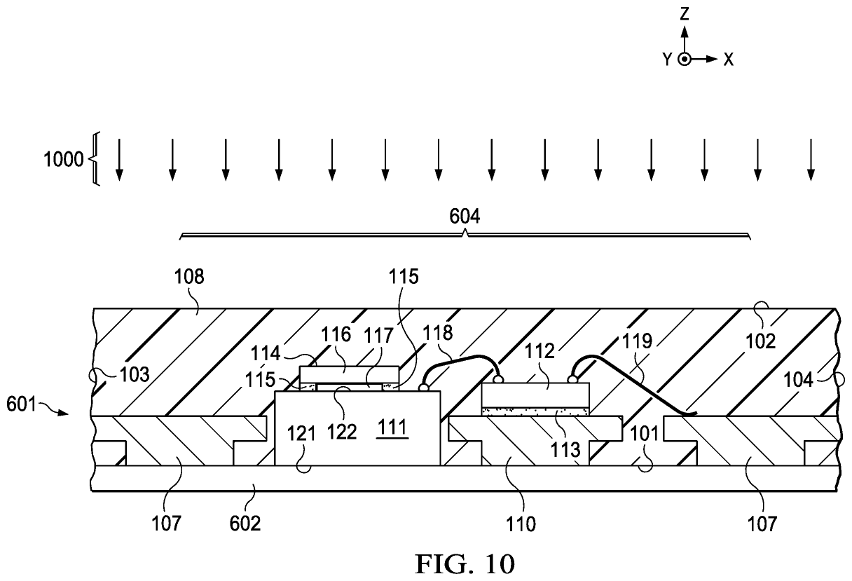

The method 200 continues at 216 in FIG. 2 with molding processing to form the molded package structure 108. FIG. 10 shows one example, in which a molding process 1000 is performed that forms the molded package structure 108 that encloses a portion of the conductive lead features 107, portions of the die attach pad 110, the bond wires 118 and 119, the first semiconductor die 111 and the cap 114 thereof, as well as the second semiconductor die 112. In the illustrated example, the molding process 1000 is performed at 216 with the carrier 602 engaged to the bottom side of the conductive lead features 107 and the bottom or first side 121 of the first semiconductor die 111.

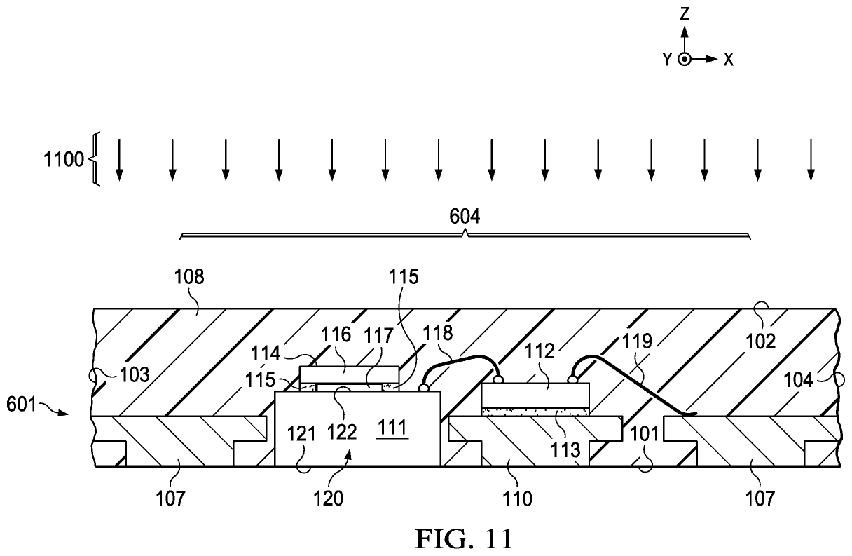

The method 200 continues at 218 in FIG. 2 with removal of the carrier tape. FIG. 11 shows one example, in which a tape removal process 1100 is performed that removes the carrier tape (e.g., carrier 602 in FIGS. 6-10 above) from the bottom or first side 101 of the molded package structure 108 and from the bottom or first side 121 of the first semiconductor die 111. In this example, the removal of the carrier 602 from the lead frame 601 and the semiconductor die 111 exposes the first side 121 of the first semiconductor die 111 and the bottom side 101 of the molded package structure 108 after performing the molding process 1000 and before etching 222 the exposed side 121 of the semiconductor die 111.

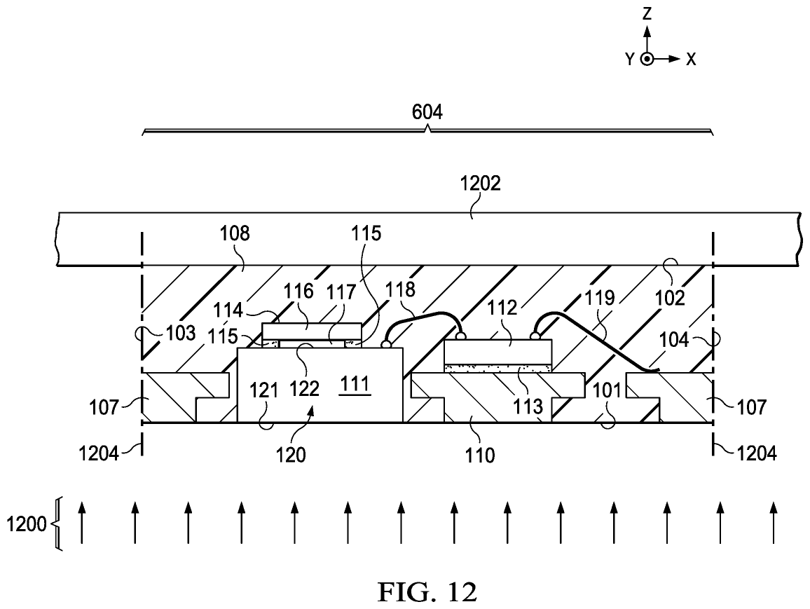

In one example, the method 200 further includes package separation at 220 in FIG. 2. FIG. 12 shows one example, in which the processed array structure is installed with the top or second side 102 of the molded package structure 108 engaging a second carrier structure 1202, and a package separation process 1200 (e.g., saw blade cutting, laser cutting, chemical etching, combinations thereof, etc.) is performed from the bottom side of the illustrated structure that separates individual packaged electronic devices from one another and from the starting array structure along lines 1204.

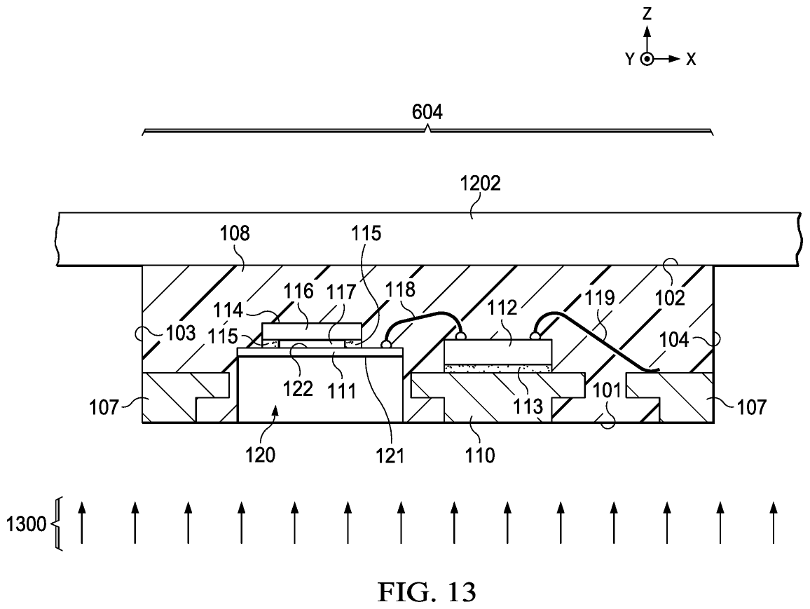

The method 200 includes etching at 222 in FIG. 2. The etching at 222 can be performed after package separation at 220 in one example or can be performed prior to package separation processing in another implementation. The etching at 222, moreover, requires no masking and is performed during packaging to form the opening 120 of the finished electronic devices 100, 132. The post molding etching at 222, moreover, eliminates the need for MEMS sensor cavity etching during wafer processing of the first semiconductor die 111, thereby reducing manufacturing cost and complexity in producing the finished electronic devices 100, 132. FIG. 13 shows one example, in which an etch process 1300 is performed while the separated electronic device remains attached to the second carrier 1202. Performing the etch processing at 222 after package separation at 220 advantageously mitigates contamination of the finished bottom side 121 of the first semiconductor die 111 with remnant materials associated with the package separation processing at 220.

The etch process 1300 forms the opening 120 that extends into the bottom side 101 of the molded package structure 108. Any suitable etch process 1300 can be used that is selective to the silicon or other semiconductor material of the first semiconductor die 111 to remove material from the first side 121 of the first semiconductor die 111 while leaving the remaining portions of the molded package structure 108 and the conductive metal structures 107 and 110 largely unaffected. The etch process 1300 sets the final thickness between the first and second sides 121 and 122 of the first semiconductor die 111 and leaves the sidewalls of the opening 120 formed by the molded package structure 108 to provide a cavity that exposes the first or bottom side 121 of the first semiconductor die 111 to allow sensing of the relative pressure between the reference pressure cavity 117 and the bottom side 121 of the first semiconductor die 111.

The described electronic devices 100 and 132 and the method 200 advantageously reduce or minimize wafer-level processing steps and cost in fabricating electronic devices, such as pressure sensors, including reducing the number of masks and etching processes during wafer processing. In addition, certain implementations can reduce the number of wafer bonding steps used in constructing pressure sensors and other MEMS-based electronic devices. In addition, the illustrated examples provide a lower profile sensor electronic device compared to stacked arrangements of multiple dies. The above devices are illustrated in the context of quad flat no lead (QFN) package types facilitate direct exposure of the sensing face of the first semiconductor die 111 to the ambient, although other implementations are possible to provide MEMS-based pressure sensors and other electronic devices having different package forms and types.

Modifications are possible in the described examples, and other implementations are possible, within the scope of the claims.

What is claimed is:

1. An electronic device, comprising:
a package structure having opposite first and second sides, opposite third and fourth sides that are spaced apart from one another along a first direction, opposite fifth and sixth sides that are spaced apart from one another along a second direction that is orthogonal to the first direction, the first and second sides being spaced apart from one another along a third direction that is orthogonal to the first and second directions, and the package structure having an opening extending into the first side along the third direction;
a first semiconductor die having a first side exposed in the opening of the package structure and an opposite second side partially enclosed by the package structure; and
a second semiconductor die electrically connected to the first semiconductor die, the second semiconductor die enclosed by the package structure and laterally spaced apart from the first semiconductor die.

2. The electronic device of claim 1, comprising a die attach pad laterally spaced apart from and at least a portion of the opening of the package structure in a plane of the first and second directions and partially enclosed by the package structure, wherein the second semiconductor die is attached to the die attach pad.

3. The electronic device of claim 2, wherein the die attach pad has a side that is partially exposed outside the package structure along the first side.

4. The electronic device of claim 1, wherein the first semiconductor die is configured to detect a sensed pressure of the first side of the first semiconductor die relative to a pressure of the second side of the first semiconductor die and to provide an electrical signal to the second semiconductor die based on the sensed pressure.

5. The electronic device of claim 1, comprising:
a conductive lead partially enclosed be the package structure and having a side that is partially exposed outside the package structure along the first side;
a first bond wire (118) electrically connected between the first semiconductor die and the second semiconductor die; and
a second bond wire (119) electrically connected between the second semiconductor die and the conductive lead.

6. The electronic device of claim 1, wherein:
the first side of the first semiconductor die is spaced apart from the first side of the package structure along the third direction; and
the package structure has sidewalls of the opening that extend along the third direction from the first side of the first semiconductor die to the first side of the package structure.

7. The electronic device of claim 1, comprising a cap attached to the second side of the first semiconductor die and forming a closed reference pressure cavity above a portion of the second side of the first semiconductor die.

8. The electronic device of claim 7, wherein the cap includes a third semiconductor die that forms a lid of the closed reference pressure cavity that is spaced apart from the second side of the first semiconductor die along the third direction, and a die attach adhesive that forms a sidewall of the closed reference pressure cavity.

9. The electronic device of claim 7, wherein the cap includes a die attach adhesive that forms: a lid of the closed reference pressure cavity that is spaced apart from the second side of the first semiconductor die along the third direction; and a sidewall of the closed reference pressure cavity.

10. The electronic device of claim 7, wherein the first semiconductor die is configured to detect a sensed pressure of the first side relative to a pressure of the reference pressure cavity and to provide an electrical signal to the second semiconductor die based on the sensed pressure.

11. A system, comprising:
a circuit board; and
an electronic device attached to the circuit board and comprising a package structure and first and second semiconductor dies;
the package structure having opposite first and second sides, opposite third and fourth sides that are spaced apart from one another along a first direction, opposite fifth and sixth sides that are spaced apart from one another along a second direction that is orthogonal to the first direction, the first and second sides being spaced apart from one another along a third direction that is orthogonal to the first and second directions, and the package structure having an opening extending into the first side along the third direction;
the first semiconductor die having a first side exposed in the opening of the package structure and an opposite second side partially enclosed by the package structure; and
the second semiconductor die electrically connected to the first semiconductor die, the second semiconductor die enclosed by the package structure and laterally spaced apart from the first semiconductor die.

12. The system of claim 11, comprising a die attach pad laterally spaced apart from and at least a portion of the opening of the package structure in a plane of the first and second directions and partially enclosed by the package structure, wherein the second semiconductor die is attached to the die attach pad.

13. The system of claim 11, wherein:
the first side of the first semiconductor die is spaced apart from the first side of the package structure along the third direction; and
the package structure has sidewalls of the opening that extend along the third direction from the first side of the first semiconductor die to the first side of the package structure.

14. The system of claim 11, comprising a cap attached to the second side of the first semiconductor die and forming a closed reference pressure cavity above a portion of the second side of the first semiconductor die.

15. The system of claim 14, wherein the first semiconductor die is configured to detect a sensed pressure of the first side relative to a pressure of the reference pressure cavity and to provide an electrical signal to the second semiconductor die based on the sensed pressure.

16. A method of fabricating an electronic device, the method comprising:
positioning a semiconductor die with a side of the semiconductor die coplanar with a bottom side of a conductive lead feature of a lead frame;
forming a molded package structure that encloses a portion of the conductive lead feature; and
etching an exposed side of the semiconductor die to form an opening extending into the bottom side of the molded package structure.

17. The method of claim 16, further comprising attaching a cap to a second side of the semiconductor die to form a closed reference pressure cavity above a portion of the second side of the semiconductor die, the cap including another semiconductor die that forms a lid of the closed reference pressure cavity that is spaced apart from the second side of the semiconductor die, and a die attach adhesive that forms a sidewall of the closed reference pressure cavity.

18. The method of claim 16, further comprising attaching a cap to a second side of the semiconductor die to form a closed reference pressure cavity above a portion of the second side of the semiconductor die, the cap including a die attach adhesive that forms: a lid of the closed reference pressure cavity that is spaced apart from the second side of the semiconductor die and a sidewall of the closed reference pressure cavity.

19. The method of claim 16, wherein:
positioning the semiconductor die includes attaching the lead frame on a carrier with the bottom side of the conductive lead feature engaging a first portion of a side of the carrier and attaching the semiconductor die on the carrier with the side of the semiconductor die engaging a second portion of the side of the carrier;
forming the molded package structure includes performing a molding process with the carrier engaged to the bottom side of the conductive lead feature and the side of the semiconductor die; and
the method further comprising removing the carrier from the lead frame and the semiconductor die to expose the side of the semiconductor die and a bottom side of the molded package structure after performing the molding process and before etching the exposed side of the semiconductor die.

20. The method of claim 16, wherein the semiconductor die is a first semiconductor die, the method further comprising, before forming the molded package structure:
attaching a second semiconductor die on a die attach pad of the lead frame;
electrically connecting a terminal of the first semiconductor die to a first terminal of the second semiconductor die; and
electrically connecting a second terminal of the second semiconductor die to a conductive lead feature of the lead frame.
